(19) United States
(12) Patent Application Publication
(10) Pub. No.: US 2008/0236494 A1
(43) Pub. Date: Oct. 2, 2008

(54) PLASMA PROCESSING APPARATUS

(76) Inventors: TADAYOSHI KAWAGUCHI, Kudamatsu (JP); Muneo Furuse, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/836,195

(22) Filed: Aug. 9, 2007

(30) Foreign Application Priority Data
Mar. 30, 2007 (JP) 2007-091722

(51) Int. Cl. C23C 16/00

(52) U.S. Cl. 118/723 R

(57) ABSTRACT

A plasma processing apparatus, comprising: a processing chamber arranged within a vacuum vessel; a sample table arranged within the processing chamber on which a sample to be processed is placed; electric field supplying means for supplying an electric field to form plasma within the processing chamber; a plate member formed of a dielectric material for constituting a ceiling plane of the processing chamber and transmitting the electric field; a cover member formed of a dielectric material for constituting a part of a side wall for the entire circumference of the processing chamber, facing the plasma, and propagating the electric field radiated from the plate member; and a conductive member internally arranged for almost the entire circumference of the cover member.

### CLAIM OF PRIORITY

The present invention application claims priority from Japanese application JP2007-091722 filed on Mar. 30, 2007, the content of which is hereby incorporated by reference into this application.

### BACKGROUND OF THE INVENTION

(1) Field of the Invention

The present invention relates to plasma processing apparatuses applied to fine processes of a semiconductor manufacturing process or the like, and particularly to a plasma processing apparatus assuring less amount of foreign matters and contamination resulting from wall surface of a processing chamber and is also capable of implementing distribution control of process plasma generated in the processing chamber.

(2) Description of the Related Art

As a semiconductor manufacturing apparatus for manufacturing semiconductor devices by processing samples (hereinafter, referred to as wafers) such as silicon wafers, a plasma processing apparatus such as plasma CVD apparatus and plasma etching apparatus has been widely utilized. In recent years, a circuit pattern has directly in the trend to realize further improvement in fine structure with progress in higher integration density of devices. Therefore, further fine processing sizes are required for such plasma processing apparatus and therefore higher etching accuracy is also required.

Moreover, with diversification of structural materials of semiconductor devices, plasma processes (etching recipe, etc.) are also complicated and diversified process gases are also used. As the requirement for semiconductor manufacturing apparatus with progress in diversification of etching processes, improvement in productivity of semiconductor devices is essential and introduction of an apparatus for stably manufacturing semiconductor devices for a long period of time, namely stabilization of mass-production for a longer period is also understood as a very important problem.

For example, the wall surface of processing chamber is chemically and physically invaded because plasma of reactive gasses such as fluoride, chloride, and moreover bromide is used in the plasma etching apparatus. Therefore, since foreign matters and metal contaminants which are not desirable for semiconductor devices are released from a wall of the processing chamber because reactive by-products are adhered to the internal wall of the processing chamber and the surface of internal wall of the processing chamber is reformed due to increase in the number of sheets of the processed wafers to manufacture the semiconductor devices, the plasma processes that are stabled for long period becomes impossible in some cases.

Moreover, in recent years, requirement in reduction of mixture of impurities such as heavy metal into processing sample is becoming more severe. Therefore aluminium included in alumina ceramics used as a plasma resisting material, aluminium as the principal element of an anode oxide film used for surface process of aluminum materials, and moreover aluminium included in alumina used for spraying process of ceramics to the surface of wall material in the processing chamber must be reduced. In addition, mixture of a rare earth metal released from a rare earth metal oxide of Yttria (for example, Yttrium oxide, etc.) and fine-quantity metal (Fe, Mg, etc.) included in such surface processing material cannot be neglected as the material in place of alumina for such spraying process and therefore it has also been required to reduce contamination resulting from the plasma resisting material.

As an example for reduction in quantity of contaminant resulting from such plasma resisting material, Japanese Patent Application Laid-Open Publication No. 2006-196804 has disclosed subject matters that a material in contact with plasma within the plasma processing chamber is formed of a material that has been constituted by including a conductive material into a base material of quartz or germanium as the amorphous material and the contact surface of plasma is provided to function as a ground electrode having the function of earth.

Moreover, in recent years, the processing size in the order of several tens of nm has been introduced for processing of devices and higher accuracy has also been required for the etching processes. In addition, with increase in the diameter of wafer up to 300 mm, higher accuracy and measures for larger diameter are also requested for the etching technology. Since gate processing in such etching technologies is a very important factor controlling operating rate and integration rate of devices, processing accuracy in such processing size is requested most severely. Therefore, uniformity of etching rate within the wafer plane and uniformity within the plane of CD become very important.

As an example of improvement in controllability of plasma distribution, Japanese Patent Application Laid-Open Publication No. H11-260596, for example, discloses the technology for controlling plasma distribution obtained by controlling active seeds with complex discharge of plasma due to radiation of electromagnetic wave based on capacity-coupled discharge plasma and high frequency for the control of plasma.

In the related art disclosed in Japanese Patent Application Laid-Open Publication No. 2006-196804, a processing chamber of a plasma processing apparatus is surrounded with a plate formed of quartz, an internal wall of the processing chamber formed of quartz or plasma resisting material, and a stage for conducting the process such as etching, etc. The internal wall of the etching chamber often uses a plasma resisting material in order to control change by aging of etching performance or the like. Process plasma used for process such as etching is generated in contact with the quartz plate but it is also in contact with the surface of a wall material within the processing chamber. Accordingly, in the case where the internal wall of the processing chamber is formed of a plasma resisting material, contaminant that is mainly formed of the material of wall surface is generated within the processing chamber and it scatters over a wafer to produce semiconductor devices, etc. In view of reducing contamination resulting from the surface of plasma resisting material, suppression of contaminant may be realized by covering a part generating contamination with quartz.

In actual, however, since high frequency is used for supply of energy of the plasma generated in the processing chamber, plasma is also generated at the part covered with quartz because the electric field generated by high frequency is propagated within the quartz material. Therefore, since plasma spreads to the internal wall of the processing chamber near the quartz cover, it is difficult to attain the object to reduce contamination resulting from the plasma resisting material of the wall surface.

Moreover, a contact surface of plasma is given the function of the earth by including a conductive material to a base material of quartz or germanium. At present, the conductive material which does not result in contaminant for semiconductor device is considered as Si or C or a mixture of these materials. However, it is now thought not adequate to constitute a contact surface of plasma using these conductive materials when etching characteristic, foreign matter, operation life, and cost are considered.

Moreover, in the related art disclosed in the Japanese Patent Application Laid-Open Publication No. H11-260596, a system thereof is likely to be increased in cost because an apparatus may be complicated and a couple of power supply systems are required due to introduction of a couple of systems of high frequency in order to generate plasma, although generation of active seed is controlled through composite discharge of capacity coupling discharge plasma and plasma due to radiation of electromagnetic wave. Moreover, since the plasma generated by radiation of electromagnetic wave is weak, stability of plasma and distribution control cannot be established simultaneously, because plasma generated in the processing chamber becomes unstable in some cases.

### SUMMARY OF THE INVENTION

Considering the problems explained above, an object of the present invention is to provide a plasma processing apparatus that can reduce generation of contamination resulting from a material of internal wall from a material of internal wall of the processing chamber and can realize distribution control of plasma generated within the processing chamber.

According to an aspect of the typical invention of the present invention, a plasma processing apparatus, comprising: a processing chamber arranged within a vacuum vessel; a sample table arranged within the processing chamber on which a sample to be processed is placed; electric field supplying means for supplying an electric field to form plasma within the processing chamber; a plate member formed of a dielectric material for constituting a ceiling plane of the processing chamber and transmitting the electric field; a cover member formed of a dielectric material for constituting a part of a side wall for the entire circumference of the processing chamber, facing the plasma, and propagating the electric field radiated from the plate member; and a conductive member internally arranged for almost the entire circumference of the cover member.

As explained above, the plasma processing apparatus according to the present invention is capable of reducing foreign matters and contaminants generated from the internal wall of the processing chamber and is also easily controlling distribution of plasma.

### BRIEF DESCRIPTION OF THE DRAWINGS

These and other features, objects and advantages of the present invention will become more apparent from the following description when taken in conjunction with the accompanying drawings wherein:

FIG. 1 is a vertical cross-sectional view showing a schematic structure of a plasma processing apparatus of a preferred embodiment of the present invention;

FIG. 2 is an enlarged schematic cross-sectional view showing the plasma processing chamber of FIG. 1;

FIG. 3A is a graph showing a result of simulation of electric field distribution intensity at the surface of an earth (an internal wall member) in the case where a quartz cover in which a conductive member of different height is provided is used in the embodiment of the present invention;

FIG. 3B is a graph showing a result of simulation of electric field distribution intensity at the surface of the earth in the case where the quartz cover in which conductive members in different numbers are provided is used in the embodiment of the present invention;

FIG. 3C is a graph showing a result of simulation of electric field distribution intensity at the surface of the earth in the case where the quartz cover in which the conductive member is provided at the positions of different vertical heights is used in the embodiment of the present invention;

FIG. 4A is an image diagram of plasma distribution in a processing chamber in the case where a quartz cover to which a conductive member is not provided is used as a comparison example;

FIG. 4B is an image diagram of plasma distribution in the case where five conductive members are provided at the upper part of the quartz cover on the basis of the embodiment of the present invention;

FIG. 4C is an image diagram of plasma distribution in the case where five conductive members are provided at the lower part of the quartz cover on the basis of the embodiment of the present invention;

FIG. 5A is a perspective view of the quartz cover wherein a ring type conductive member is provided in relation to the embodiment of the present invention; and

FIG. 5B is a perspective view of the quartz cover wherein an arcuate conductive member is provided in relation to the modification of the present invention.

### DESCRIPTION OF THE PREFERRED EMBODIMENTS

The best mode for embodying the present invention will be explained below with reference to the accompanying drawings.

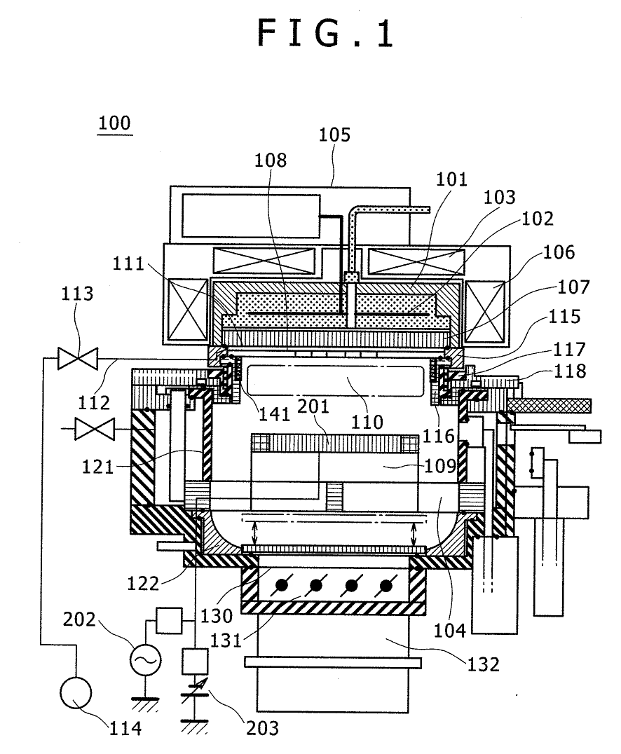

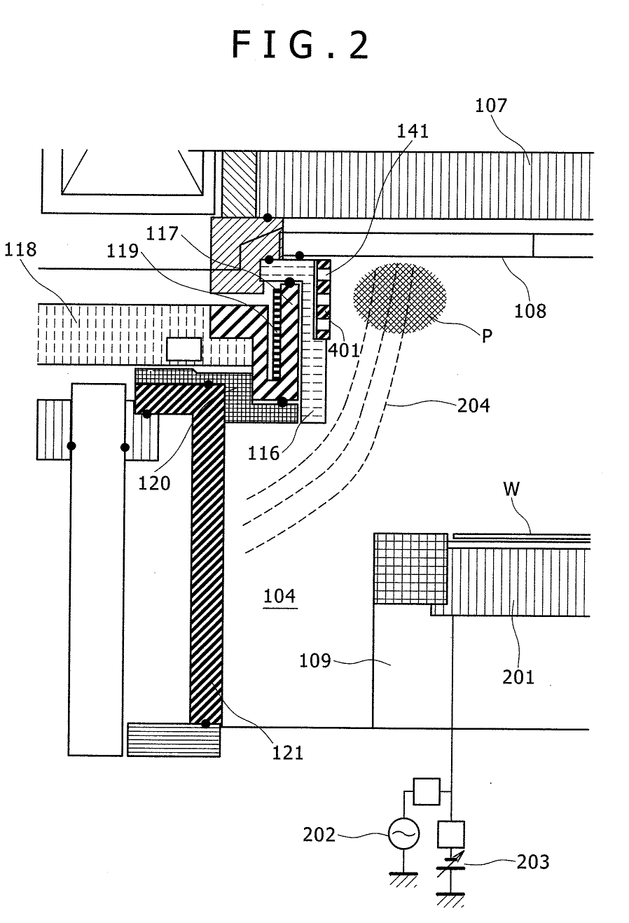

A structure of a plasma processing apparatus as an embodiment of the present invention will be explained by referring to FIG. 1. FIG. 1 is a schematic vertical cross-sectional view showing the plasma processing apparatus of this embodiment. FIG. 2 is an enlarged cross-sectional view of the plasma processing apparatus of FIG. 1.

A discharge chamber is arranged on a vacuum processing chamber 104 of the plasma processing apparatus 100. This discharge chamber is constituted with inclusion of a cover member 101 constituting a cover of a vacuum vessel, an antenna 102 arranged at the interior of the cover member 101, a magnetic-field generating unit 103 arranged surrounding the discharge chamber arranged at a side and an upper part of the antenna 102, and a ceiling member arranged at the lower part of the antenna 102. Moreover, at the upper part of the magnetic-field generating unit 103, a power supply unit 105 is arranged for supplying electrical powers in the VHF and UHF bands ranging from 200 MHz to 1 GHz outputted from the antenna 102.

The antenna 102 for supplying electrical powers to the processing chamber 104 is arranged at the interior of the cover member 101 constituted with a conductive member such as SUS and a dielectric material 106 is arranged between the antenna 102 and the cover material 101 to insulate these elements and to transfer the electromagnetic wave emitted from the antenna 102 to the ceiling member side at the upper part.

Moreover, the ceiling member includes a quartz plate 107 constituted with a dielectric material of quartz (SiO₂) or the like for transferring the transmitted electromagnetic wave to the internal side of processing chamber at the lower part and a shower plate 108, to which multiple holes are formed, arranged at the lower part of the quartz plate 107 for dispersively guiding the supplied process gas to the interior of the processing chamber.

An upper space of the processing chamber 104 formed at the lower part of the shower plate 108 and at the upper part of a sample table 109 is provided as the discharge chamber 110 to form plasma with so-called ECR (Electron Magnetic Field Resonance) caused by mutual effects of the electromagnetic wave from the antenna 102 guided through the shower plate 108 to the supplied process gas and the magnetic field supplied from the electromagnetic field generating unit 103. Moreover, distribution of plasma may be controlled with control of the magnetic field.

Meanwhile, a space at the upper part of the shower plate 108 is provided as a buffer chamber 111 arranged to allow the process gas to dispersively enter the discharge chamber 110 from multiple holes. This process gas is supplied, from a controller 114 for regulating flow rate thereof, to the processing chamber via a process gas line 112 and a process gas shielding valve 113.

As explained above, the process gas is dispersively guided into the discharge chamber 110 from multiple holes of the shower plate 108. These holes of the shower plate 108 are mainly arranged to the location opposing to that where a sample is placed on the sample table 109 in view of equalizing density of plasma in the discharge chamber 110 in combination with the operation of the buffer chamber 111 for uniformly dispersing the process gas. Moreover, a lower ring 115 is arranged in the external circumference side of the quartz plate 107 and shower plate 108 at the lower part of the cover member 101. At the interior of this lower ring 115, a gas channel that is communicated with a gas line 112 for allowing the process gas to flow into the buffer chamber 111 is provided.

Moreover, at the lower part of the shower plate 108, an internal wall member of discharge chamber 116 is provided, facing to the plasma at the internal side of the vacuum vessel, to define the space of the discharge chamber 110. This internal wall member 116 of the discharge chamber 116 is constituted with a conductive material such as aluminium in a hollow cylindrical shape with a flange.

At the internal side of this internal wall member 116, a dielectric material cover 141 of quarts (SiO₂) or silicon carbide (SiC) including built-in conductive member (hereinafter, referred to as quartz cover) is arranged. In addition, as shown in FIG. 2, the external circumferential side of the internal wall member 116 is surrounded with an external side wall member 117 of discharge chamber made of an electrical insulating material provided via a fine gap. Moreover, a wound heater 119 is arranged to a recessed groove of the external circumferential side and therefore surface temperature of the internal wall member 116 placed in contact therewith can be adjusted by regulating temperature of the external side wall member 117. Furthermore, the external side wall member 117 is held with the lower surface in the external circumferential side thereof being placed in contact with the conductive material plate 120 and a base plate 118 of the discharge chamber.

The sample table 109 is arranged at the internal side of internal side chambers 121, 122 and a lower internal side chamber 122 is arranged at the lower part of a block of the sample table 109. An aperture 130 is arranged at the center area of this internal side chamber 122. The aperture 130 is communicated with exhaust means provided with an exhaust valve 131 and an exhaust pump 132 provided at the lower part of the internal side chamber 122 and the sample table 109 and allows the gas within the internal side chamber 121 to flow circumference of the sample table 109.

The exhaust valve 131 as the exhaust means of the vacuum processing chamber 104 is provided with multiple plate shutters for assuring communication or non-communication between the exhaust pump 132 provided at the lower part thereof and the internal space of the internal chamber 122. Namely, the exhaust valve 131 is constituted as a shutter type exhaust valve for adjusting an exhaust rate and a flow rate by variably adjusting an area of an opening exhaust channel through rotation of the shutters. As explained above, in this embodiment, exhaust means is arranged at the lower part, particularly at the just lower part of the sample table 109. Accordingly, plasma, processing gas, and reaction byproduct within the space at the upper part of the sample table 109 within the internal side chamber 121 flow into the exhaust channel up to the exhaust valve 131 via the space within the internal side chamber 122 at the circumference and the lower part of the sample table 109.

The internal side wall member 116 is grounded through the earth via the external side wall member 117, base plate 118 or plate 120 and also has a function as the earth for plasma.

A wafer placing surface of the sample table 109 is provided as an electrostatic attracting electrode 201 and receives the electrical power for electrostatic attraction from a DC power supply 203. Moreover, a bias electrical power is also impressed to the electrostatic attracting electrode 201 from a bias power supply 202.

As is apparent from FIG. 2, a flange is provided at the upper part of the internal wall member 116 and the internal circumference side thereof is formed as a large diameter part (a thinner part). The quartz cover 141 including an embedded ring type conductive material 401 is provided here (almost for the entire circumferential part of the internal side wall of the processing chamber 104). The lower part of the internal side wall member 116 is formed as a small diameter part (a thick part) and a radius of the small diameter part is equal to or a little larger than that of the internal circumferential side of the quartz cover 141. The external side except for the flange of the internal side wall member 116 has an external diameter at both upper and lower parts.

In the example of FIG. 2, the ring type conductive member 401 is embedded in three stages in an equal interval at the upper and lower parts of the quartz cover 141. Both upper end surfaces of the flange of the internal wall member 116 and the quartz cover 141 are facing, in almost the contact condition, to the lower surface of the dielectric material shower plate 108 constituting the ceiling plane. Here, a width in the radius direction of the ring type conductive member 401 is larger than the distance between the internal circumferential end of the conductive material and the internal circumferential surface of the thinner part of the wall member of in the side of the internal wall member 116 (it will be explained later).

Next, operations of the plasma processing apparatus 100 of this embodiment will be explained.

First, a semiconductor wafer W as an object of the process is carried into the processing chamber 104 from a transfer unit and is thereafter placed for attraction on the electrostatic attracting electrode 201 of the sample table 109. A gas, for example, a gas including the halogen gas required for etching of the semiconductor wafer W is supplied from the process gas line 112 and is also supplied into the processing chamber 104 in a mixing ratio of the predetermined flow rate. Simultaneously, the interior of the processing chamber 104 is adjusted to the predetermined processing pressure with the exhaust pump 132 and exhaust valve 131 and the electromagnetic wave is radiated from the antenna 102 through supply of electrical power from the power supply unit 105. With mutual effects of almost horizontal magnetic field generated within the processing chamber 104 with the magnetic field generating unit 103 and the electromagnetic wave from the antenna 102, plasma P can be generated effectively within the processing chamber 104 to generate ions and radicals through dissociation of the process gas. Moreover, electrical power of bias voltage from the bias power supply 202 of the electrostatic attracting electrode 201 controls an incident energy to the semiconductor wafer W of the ion. The wanted etching shape can be obtained by etching the semiconductor wafer W by utilizing these ion and radical.

In the plasma processing apparatus illustrated in this embodiment, the electric field at the area near the external circumference is intensified just at the lower part of the shower plate 108 with high frequency electric field radiated from the antenna 102. In addition, plasma P is further intensified in the density with resonance with a magnetic field 204 generated by a coil current of the magnetic field generating unit 103.

Here, generation of contaminants can be controlled by providing the cover 141 formed of the dielectric material such as quartz in view of controlling amount of removal with the plasma P of the internal wall member 116. However, since quartz is a dielectric material, electric field may also be generated on the surface of the cover 141 of quartz or the like because high frequency is propagated within the quartz. Accordingly, plasma may also be generated on the surface of quartz and the internal wall member 116 at the lower side of the quartz cover.

If the cover is formed of a conductive member, the high frequency element is not propagated into the cover. Therefore, no plasma is generated with the electric field from the cover. However, a material of the conductive member which does not generate any contaminant is understood as Si or C or a mixture of these elements at present. But, it is difficult for these substances to be applied in direct to the cover 141 when etching characteristic, foreign matter (influence on semiconductor device), operation life, and cost thereof are taken into consideration.

In this embodiment, the structure including a built-in conductive member within quartz as the material which does not generate any contaminant shows the performances satisfying the conditions explained above.

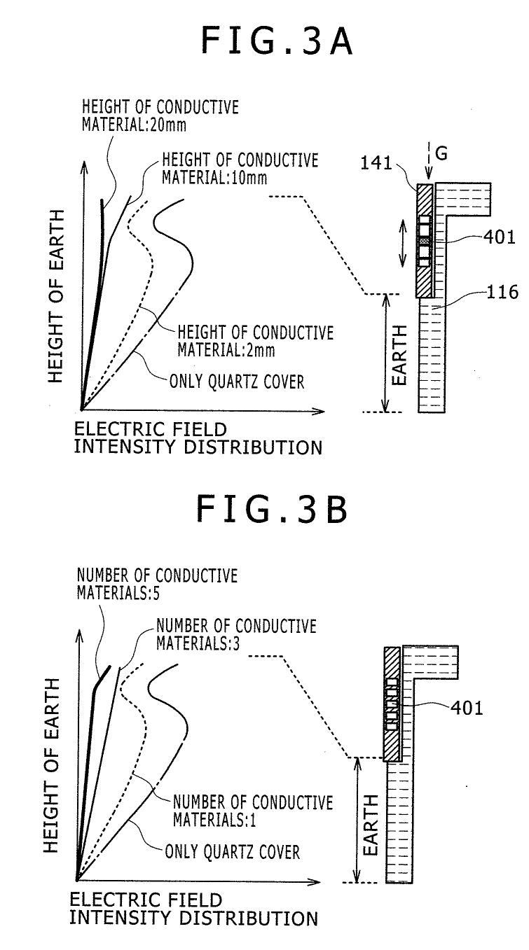

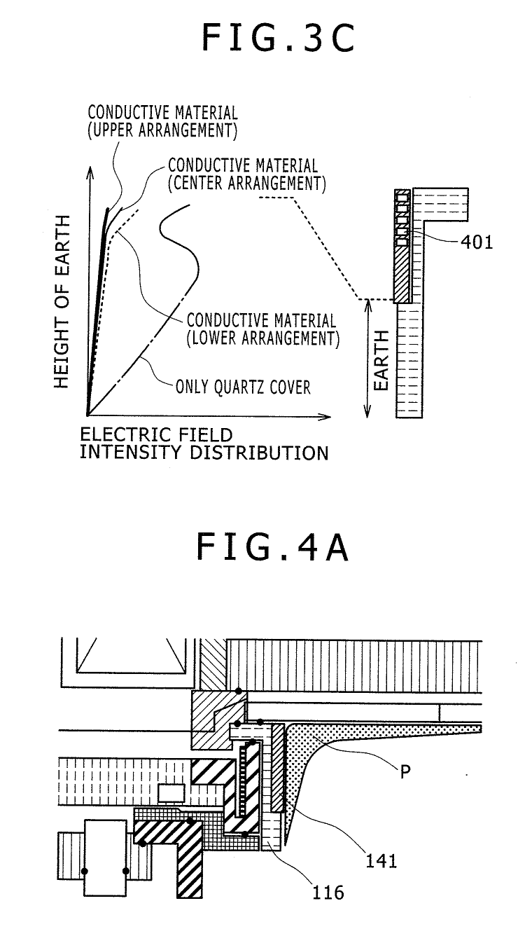

In regard to this point, results of electric field distribution simulation related to the embodiment of the present invention will be explained with reference to FIG. 3A, FIG. 3B, and FIG. 3C. These results are characteristics obtained when the electrical power of the UHF band frequency of 450 MHz is supplied from the power supply unit. In these FIGS. 3A to 3C, only the part of the internal wall member 116 at the lower side where the quartz cover 141 is not provided in the height direction of the internal wall member 116 is defined as “earth”, while height in the upper direction from the lower end of the internal wall member 116 (in other words, the direction going nearer to the side of the dielectric material shower plate 108 forming the ceiling plane) is defined as “height of earth”. Namely, “height of earth” corresponding to the electric field distribution intensity in the left side of FIGS. 3A to 3C can be attained by magnifying the part indicated as “earth” of the internal wall member in the right side of FIGS. 3A to 3C in the height direction as indicated with a broken line.

First, FIG. 3A shows results of the electric field distribution intensity simulation at the surface of earth (internal wall member 116) in the case where the quartz cover 141 including a built-in conductive member 401 of different height is used.

According to this FIG. 3A, electric field intensity is considerably intensified as the height of earth increases in the case where the quartz cover 141 does not include the conductive member 401. Meanwhile, electric field intensity at the surface of the “earth”, namely at the internal wall member 116 in the lower side of the quartz cover is rather reduced by providing the conductive member 401 in the height of 2 mm within the quartz cover 141. Moreover, reduction effect of the electric field intensity can be enhanced by increasing height of the conductive member 401 by 10 mm, moreover, by 20 mm. Accordingly, it may be understood that generation of plasma due to the electric field from the quartz cover is suppressed by changing the height of the conductive member. However, increase in the height of a conductive member 401 is effective for reduction in the electric field intensity but is likely to reduce intensity of the quartz cover because process of the quartz cover becomes difficult.

FIG. 3B shows the results in the case where a measure to overcome such problem is provided. That is, FIG. 3B shows, in such embodiment, the results of simulation of electric field intensity distribution at each surface of the earth using the quartz cover including no built-in conductive member 401 (only the quartz cover) and that including one, three, or five built-in conductive members 401 in the same height of 3 mm. According to this embodiment, electric field intensity at the surface of the internal wall member in the lower side of the quartz cover can be reduced by providing many conductive members 401, and thereby the results identical to that mentioned above can be attained. In FIG. 3B, the most effective result has been obtained when five conductive members 401 are built in.

FIG. 3C shows the results under the condition that five conductive members shown in FIG. 3B are built in the quartz cover and these conductive members 401 are further moved in parallel in the vertical directions from the original state. According to this embodiment, it has been proved that when the five conductive members are built in the uppermost side of the quartz cover, the electric field intensity distribution of the earth is further lowered than that in the case where such members are built in the lower side.

In summary, the result that it is effective to provide multiple conductive members 401 into the quartz cover, moreover, to arrange these members at the upper part of the quartz cover from the viewpoint of reduction in amount of removal, processing ability, and intensity of the internal wall member has been obtained.

The plasma processing apparatus of the present invention is capable of controlling distribution of plasma generated in the processing chamber with magnetic field and if the magnetic field is weak, stability and distribution control of plasma are not compatible in some cases because plasma becomes unstable in accordance with the process conditions.

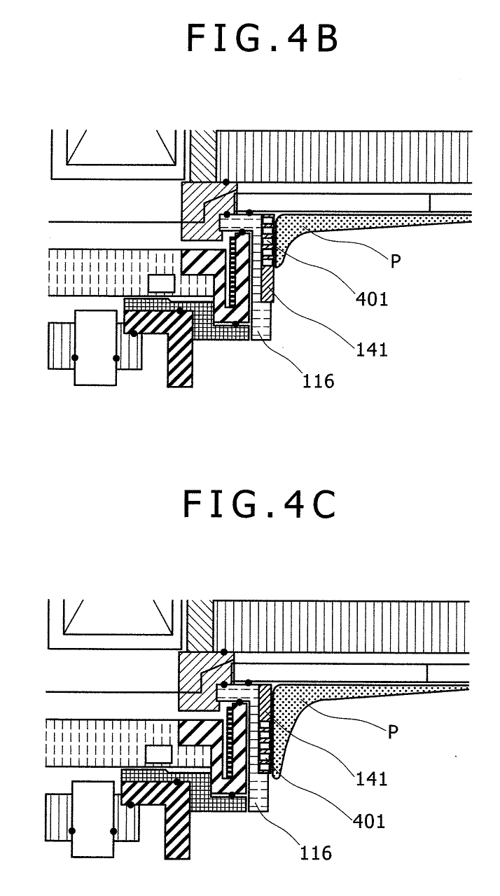

Therefore, distribution of plasma can be controlled and adjusted under stable condition by providing a conductive member within the quartz cover. This will be explained with reference to FIGS. 4A, 4B, and 4C.

FIG. 4A is an image diagram showing distribution of plasma in the processing chamber 104 in the case where the quartz cover 141 not including the built-in conductive member is used. In this case, since quartz is a dielectric material, plasma is also generated on the surface of the quartz cover because the electric field is propagated into quartz and thereby an etching rate at the external circumference of wafer becomes high.

Meanwhile, FIG. 4B is an image diagram showing distribution of plasma in the case where five conductive members 401 are built in the upper part of the quartz cover 141. In this case, since the electric field is reduced with the conductive member, plasma at the surface of the quartz cover is pretty reduced and thereby an etching rate at the external circumference of wafer is remarkably lowered in comparison with that in FIG. 4A.

Moreover, FIG. 4C is an image diagram showing distribution of plasma in the case where five conductive members are built in the lower part of the quartz cover 141. In this case, since the electric field is reduced with the conductive member, plasma at the surface of the quartz cover is set to the intermediate condition between the conditions in FIG. 4A and FIG. 4B and thereby an etching rate at the external circumference of wafer is lowered in comparison with that in FIG. 4A.

In the plasma processing apparatus, when the quartz cover not including the built-in conductive member is used, the gap G (refer to FIG. 3A) provided between the quartz cover 141 and the thinner part of the internal wall member 116 at the rear surface (at the external side in the radius direction) supporting the same quartz cover has applied a certain influence on plasma. Therefore, highly accurate size tolerance has been requested for the quartz cover. On the other hand, in the case of the quartz cover including the built-in conductive member 401 in this embodiment, the conductive member 401 works as the earth for the high frequency element propagated within the quartz cover 141. In this case, a width in the radius direction of the ring type conductive member 401 is, for example, 3 mm and this width is larger than a distance (thickness of thinner part (for example, 2 mm)+gap G) between the internal circumferential end of the conductive member 401 and the internal circumferential surface of the thinner part of the side wall member 116. As a result, the gap G between the quartz cover and the earth in the side of radius direction thereof can be neglected. Accordingly, influence applied on the plasma generated within the etching chamber can be reduced, even if size tolerance of the quartz cover is not given the higher accuracy.

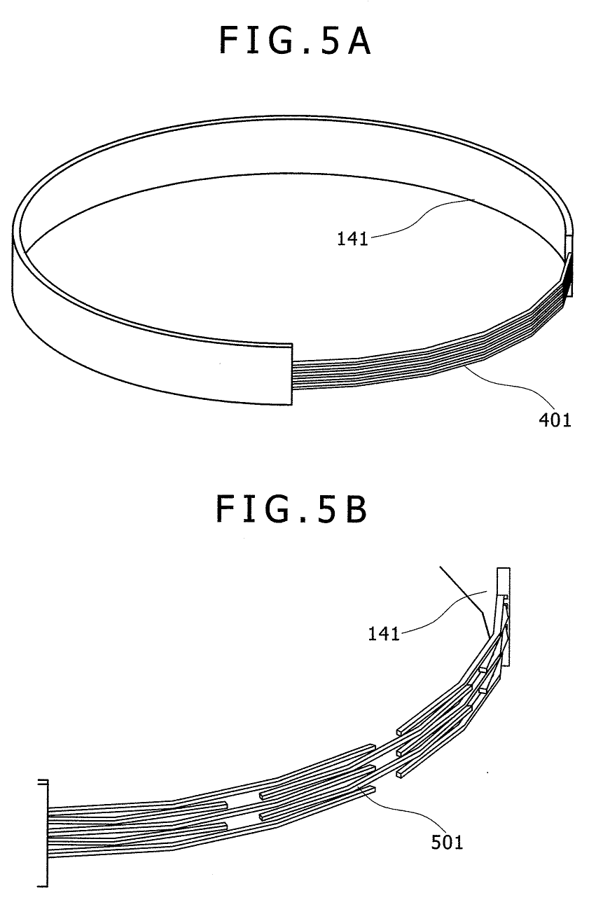

Next, a concrete example of structure and a concrete manufacturing method of the quartz cover 141 including the built-in conductive member 401 will be explained with reference to FIGS. 5A and 5B.

First, FIG. 5A is a perspective view of the ring type quartz cover 141 including therein multiple ring type conductive members 401. Thickness of the quartz cover 141 is 7 mm and height thereof is 37 mm. The quartz cover 141 is provided with ring type cavity (groove) in height of 3 mm and a width of 3 mm at the five positions in the height direction. Thickness of the quartz covers (side walls) in both sides of the cavity is 2 mm, respectively. This cavity has a structure to which the ring type conductive member 401 may be provided.

As a material of the conductive member to be provided within the quartz cover, a high melting point metal such as Mo or W and a material including carbon are suitable. Moreover, on the occasion of forming the cavity to the quartz cover 141, the side walls in both sides of the cavity are respectively required to have the thickness of about 2.0±0.5 mm in order to assure strength of the quartz cover.

Here, the conductive member 401 may be built, for example, into the ring type quartz cover 141 with the following procedures. For example, in the case of providing five conductive members 401, the ring type cavity (channel) of the predetermined depth is formed first, with the laser process or the like, extending to the entire part of the circumference from the upper side of the ring type quartz cover 141. Next, a first ring type conductive member 401 is inserted into this channel. Thereafter, the quartz ring of the predetermined height having the width almost equal to that of the cavity is inserted into the upper side of the first conductive member 401. Next, a second ring type conductive member 401 is then inserted thereon and a second quartz ring is also inserted. In addition, a third conductive member 401 and a quartz ring are also laminated alternately and sequentially in view of finally completing the quartz cover including the five conductive members.

If it is requested to manufacture the conductive member as a continuous ring type conductive member in regard to the shape of conductive member, processes may become difficult and expensive in a certain case.

Therefore, as an alternative, a ring type conductive member as a whole may be formed by combining multiple arcuate conductive members 501 in the circumference direction as shown in FIG. 5B. In this case, it is possible to constitute a structure disabling easier propagation of the high frequency element by arranging the arcuate conductive members in different steps. In addition, it may also be considered to form a structure of the coiled conductive members by bundling multiple thin lead wires.

In the first embodiment, the side wall member 116 is formed as a member having the diameter smaller than that of the internal chamber 121, but it is matter of course that these elements are constituted as the members having the equal diameter.

What is claimed is:

1. A plasma processing apparatus, comprising:
a processing chamber arranged within a vacuum vessel;
a sample table arranged within the processing chamber on which a sample to be processed is placed;
electric field supplying means for supplying an electric field to form plasma within the processing chamber;
a plate member formed of a dielectric material for constituting a ceiling plane of the processing chamber and transmitting the electric field;
a cover member formed of a dielectric material for constituting a part of a side wall for the entire circumference of the processing chamber, facing the plasma, and propagating the electric field radiated from the plate member; and
a conductive member internally arranged for almost the entire circumference of the cover member.

2. The plasma processing apparatus according to claim 1, comprising:
a conductive side wall member for constituting a part of a side wall for the entire circumference of the processing chamber and facing the plasma at least at a part;
wherein the side wall member is constituted as a thinner part having a large diameter of the internal circumference at the upper part and as a thick part having a small diameter of the internal circumference at the lower part; and
the cover member is held in the internal circumference side of the thinner part of the side wall member.

3. The plasma processing apparatus according to claim 2,
wherein a width in the radius direction of the conductive member is larger than a distance between an internal circumferential end of the conductive member and an internal circumferential surface of the thinner part of the side wall member.

4. The plasma processing apparatus according to claim 1,
wherein a plurality of the conductive members are arranged within the cover member keeping an interval in the height direction.

5. A plasma processing apparatus, comprising:
a processing chamber arranged within a vacuum vessel;
electric field supplying means for supplying an electric field to form plasma within the processing chamber;
a magnetic field generating unit for generating magnetic field within the processing chamber;
a plate member formed of a dielectric material for constituting a ceiling plane of the processing chamber and transmitting the electric field;
a cover member formed of a dielectric material for constituting a part of a side wall for the entire circumference of the processing chamber, facing the plasma at least at a part, and propagating an electric field radiated from the plate member; and
a conductive member arranged within the cover member;
wherein the plasma processing apparatus is configured such that a distribution of the plasma in the processing chamber being capable of controlling in accordance with position in the height direction of or the number of the conductive members within the cover member.

6. The plasma processing apparatus according to claim 5, comprising:
a conductive side wall member for constituting a part of the side wall of the processing chamber and facing the plasma at least at a part;
wherein the cover member is held with the conductive side wall member under the condition that the cover member is almost in contact with the area just under the dielectric material plate member.

7. The plasma processing apparatus according to claim 5,
wherein the conductive member is formed in the shape of a ring and the plurality of conductive members are built in the upper part of the cover member.

8. The plasma processing apparatus according to claim 5,
wherein the conductive member is formed in the arcuate shape and the plurality of conductive members are arranged in different steps almost in the shape of ring within the cover member.

9. A plasma processing apparatus, comprising:
a sample table arranged at the lower part of a processing chamber arranged within a vacuum vessel on which a sample to be processed is placed;
a power supply for supplying high frequency electrical power to an electrode within the sample table;
electric field supplying means for supplying an electric field having frequency of the UHF or VHF band to form plasma within the processing chamber from the upper part of the processing chamber;
a magnetic field generating unit for forming magnetic field in the processing chamber;
a plate member formed of a dielectric material for constituting a ceiling plane of the processing chamber and transmitting the electric field;
a conductive side wall member for constituting a part of a side wall for the entire circumference of the processing chamber and facing the plasma at least at a part;
a cylindrical conductive cover member held with the side wall member for constituting a part of the side wall for the entire circumference of the processing chamber, facing the plasma, and propagating the electric field radiated from the plate member; and
a conductive member internally arranged for almost the entire circumference in the internal side of the cover member.

10. The plasma processing apparatus according to claim 9,
wherein the cover member comprises a ring type cavity for storing the conductive member and thickness of the cover member in both sides of the cavity is respectively 2.0±0.5 mm.
